(19) United States
(12) Patent Application Publication
(10) Pub. No.: US 2026/0045760 A1
(43) Pub. Date: Feb. 12, 2026

(54) EARLY DETECTION OF DEAD DIODE LASER IN A LASER PUMP MODULE

(71) Applicant: Lumentum Operations LLC, San Jose, CA (US)

(72) Inventors: Li FAN, San Jose, CA (US); Supakan MALEE, Khlong Luang (TH); Titiya VAPEENAE, Khlong Luang (TH); Sasiprapa SRICHAIYO, Khlong Luang (TH)

(21) Appl. No.: 18/928,963

(22) Filed: Oct. 28, 2024

Related U.S. Application Data
(60) Provisional application No. 63/681,295, filed on Aug. 9, 2024.

(51) Int. Cl. H01S 5/00; H01S 5/023; H01S 5/02345

(52) U.S. Cl. CPC H01S 5/0014; H01S 5/023; H01S 5/02345

(57) ABSTRACT

A method of manufacturing a laser pump module includes mounting a plurality of chip-on-submount (CoS) modules to the laser pump module; wire bonding the plurality of CoS modules with bond wires, wherein the bond wires are provided such that the plurality of CoS modules form one or more conductive paths with one or more electrical conductors of the laser pump module; applying a current to one or more conductive paths to cause a spontaneous light emission by each CoS module; acquiring, while the current is applied to the one or more conductive paths, a spontaneous emission photo of the plurality of CoS modules; evaluating the spontaneous emission photo for the spontaneous light emission of each respective laser diode chip to obtain an evaluation result; and determining, based on the evaluation result, whether the spontaneous light emission has failed at one or more respective laser diode chips.

### CROSS-REFERENCE TO RELATED APPLICATION

This Patent Application claims priority to U.S. Provisional Ser. No. 63/681,295 , filed on Aug. 9, 2024, and entitled “EARLY DETECTION OF DEAD DIODE LASER IN A LASER PUMP MODULE. ” The disclosure of the prior Application is considered part of and is incorporated by reference into this Patent Application.

### TECHNICAL FIELD

The present disclosure relates generally to methods of early detection of a dead diode laser in a laser pump module and methods of manufacturing a laser pump module based on the early detection.

### BACKGROUND

An industrial diode laser (IDL) is a semiconductor device that emits coherent light when an electrical current is passed through the semiconductor device. IDLs are widely used in various industrial applications due to their efficiency, compact size, and high reliability. A pump module in an IDL system is a component responsible for providing energy to a laser medium to initiate and sustain a lasing process. In the context of diode-pumped solid-state lasers (DPSSLs) or fiber lasers, the pump module typically includes high-power laser diodes that supply the energy required to “pump” a laser gain medium (e.g., a solid-state crystal or an optical fiber with a core doped with rare-earth elements).

A pump module may include a diode laser array, a cooling system, optics and beam shaping optical components, an electrical driver, and mounting and housing assemblies. The diode laser array may be an array of semiconductor laser diodes. The semiconductor laser diodes may be designed to emit light at specific wavelengths that are efficiently absorbed by the laser gain medium. Since high-power laser diodes generate significant heat, an efficient cooling system may be provided to maintain stable operation of the pump module. The cooling system may include heat sinks, thermoelectric coolers (TECs), or liquid cooling systems to dissipate generated heat. In addition, light emitted by laser diodes may need to be focused or shaped to match one or more requirements of the laser gain medium. Optical components such as lenses, mirrors, and beam combiners may be provided to direct and shape the pump light appropriately. Additionally, the laser diodes require a stable and controllable electrical current to operate. The electrical driver may provide a stable electrical current, often with features to modulate an output power of the laser diodes and to protect the laser diodes from electrical surges. The components of the pump module may be securely mounted within a housing that protects the components from environmental factors and mechanical damage. The housing may also provide one or more interfaces for electrical connections and for the cooling system.

In operation, the electrical driver may supply current to the diode laser array, causing the laser diodes to emit light (e.g., pump light) at specific wavelengths. The pump light from the diode lasers may be directed and shaped using optical components to ensure efficient coupling into the laser gain medium. The laser gain medium may absorb the pump light, which raises electrons in the laser gain medium to higher energy levels. When the electrons return to a ground state, the electrons release photons, contributing to the lasing process. Thus, the laser gain medium is stimulated by the pump light to produce amplified light by stimulated emission.

The laser gain medium effectively increases an intensity of the light by converting the energy stored in the excited electrons into coherent light. For continuous laser operation, the pump module must continuously supply energy to the laser gain medium to maintain population inversion, a condition where more electrons are in excited states than in the ground state. This continuous supply of energy ensures a steady stream of stimulated emission, thereby sustaining the laser output. The cooling system may continuously remove excess heat generated by the laser diodes to maintain stable operation and prevent overheating, which could damage the laser diodes or degrade performance.

### SUMMARY

In some implementations, a method of manufacturing a laser pump module includes assembling a plurality of chip-on-submount (CoS) modules, wherein each CoS module of the plurality of CoS modules includes a respective laser diode chip mounted to a respective submount substrate, wherein each respective laser diode chip comprises a respective array of laser diodes; mounting the plurality of CoS modules to the laser pump module, wherein the laser pump module includes an optical output configured to be coupled to an optical fiber, an input conductor configured to receive a current, an output conductor configured to output the current, and one or more electrical conductors arranged to form a conductive path with the input conductor and the output conductor for conducting the current between the input conductor and the output conductor; wire bonding each CoS module of the plurality of CoS modules such that bond wires coupled to the plurality of CoS modules form part of the conductive path, wherein the bond wires are configured to provide the current to each respective laser diode chip of the plurality of CoS modules; applying the current to the input conductor to generate a spontaneous light emission by each respective laser diode chip, wherein the current is less than a lasing threshold of each respective laser diode chip; acquiring, while the current is applied to the input conductor, a spontaneous emission photo of the plurality of CoS modules; evaluating the spontaneous emission photo for the spontaneous light emission of each respective laser diode chip to obtain an evaluation result; and determining, based on the evaluation result, whether the spontaneous light emission has failed at one or more respective laser diode chips.

In some implementations, a method of manufacturing a laser pump module includes mounting a plurality of CoS modules to the laser pump module, wherein each CoS module of the plurality of CoS modules includes a respective laser diode chip mounted to a respective submount substrate, wherein each respective laser diode chip comprises a respective array of laser diodes, and wherein the laser pump module includes an optical output configured to be coupled to an optical fiber, and includes one or more electrical conductors; wire bonding the plurality of CoS modules with bond wires, wherein the bond wires are provided such that the plurality of CoS modules form one or more conductive paths with the one or more electrical conductors; applying a current to the one or more conductive paths to cause a spontaneous light emission by each respective laser diode chip, wherein the current is less than a lasing threshold of each respective laser diode chip; acquiring, while the current is applied to the one or more conductive paths, a spontaneous emission photo of the plurality of CoS modules; evaluating the spontaneous emission photo for the spontaneous light emission of each respective laser diode chip to obtain an evaluation result; and determining, based on the evaluation result, whether the spontaneous light emission has failed at one or more respective laser diode chips.

### BRIEF DESCRIPTION OF THE DRAWINGS

FIGS. 1A and 1B show a CoS module according to one or more implementations.

FIGS. 2A-2F show an example process flow for a method of manufacturing a laser pump module according to one or more implementations.

FIG. 3 is a flowchart of an example process associated with early detection of dead laser diodes in a laser pump module.

### DETAILED DESCRIPTION

The following detailed description of example implementations refers to the accompanying drawings. The same reference numbers in different drawings may identify the same or similar elements.

A chip-on-submount (CoS) architecture is a package type for diode laser modules. In particular, a CoS method is a packaging and mounting technique used in the construction of laser diodes, particularly in pump modules for IDLs. A CoS module may include a laser diode chip, a conductive interconnect layer, a submount, and electrical connections between the laser diode chip and the conductive interconnect layer. The laser diode chip is a semiconductor device that may emit coherent light when current is passed through the laser diode chip. The submount is a material platform onto which the laser diode chip is mounted. The submount provides a mechanical base and may have good thermal conductivity to help dissipate heat generated by the laser diodes during operation. The submount provides a stable platform for the laser diode chip, ensuring that the laser diode chip remains securely in place during operation. This stability may be important for maintaining precise alignment and preventing mechanical stress that could damage the laser diode chip. The laser diode chip may be mounted onto the submount using techniques such as soldering, adhesive bonding, or flip-chip bonding, depending on the specific requirements for thermal and electrical conductivity. Electrical connections may be made between the laser diode chip and electrical contacts of the submount using wire bonding techniques, ensuring reliable electrical connections for power supply and control.

Dead laser diodes, where one or more laser diodes do not function, may be present in a laser pump module. Detecting dead laser diodes may be difficult to detect during assembly. Put another way, during assembly of laser pump modules with CoS modules in a production line, a dead laser diode may be present in the laser pump module at the time the CoS modules are soldered into the laser pump module. The laser pump module with a dead laser diode may fail a module power specification later during a testing phase. Unfortunately, the testing phase is typically performed late in an assembly process of the laser pump module, and a dead laser diode is typically not discovered until after additional optical components are installed in the laser pump module. The additional optical components may provide optical alignment between the CoS modules and an optical output of the laser pump module. After the dead diodes are discovered, the laser pump module may be discarded, which may cause labor and material waste.

Some implementations described herein provide a method for detecting dead laser diodes in earlier stages of assembling a laser pump module having a CoS architecture. A low current may be applied to a laser pump module right after CoS modules are soldered to the laser pump module and wire bonding is provided to connect all CoS modules in the laser pump module. The low current may be below a laser current threshold. In other words, the low current may be less than a lasing threshold of each CoS module. When the low current is applied, spontaneous light emission of each CoS module may be observed. The spontaneous light emission may be near-infrared light, which is invisible to the human eye. Thus, to observe the spontaneous light emission, an electronic detector may be used to capture the spontaneous light emission of each CoS module. For example, a spontaneous emission photo may be taken by a camera while the low current is applied, and dark spots, indicating one or more dead laser diodes, may be detected by user observation of the spontaneous emission photo or by image analysis of the spontaneous emission photo performed by a processor. A dark spot in the spontaneous light emission photo at a location of a CoS module may indicate that a laser diode chip of the CoS module is defective. For example, the laser diode chip may have been damaged and/or may have a defective, non-operational laser diode. As a result of detecting a dark spot (e.g., a dead laser diode), assembling the laser pump module can be stopped or the defective CoS module may be replaced with a non-faulty CoS module. As a result, labor and material waste may be reduced and more efficient mass production of laser pump modules may be realized, which may save energy resources.

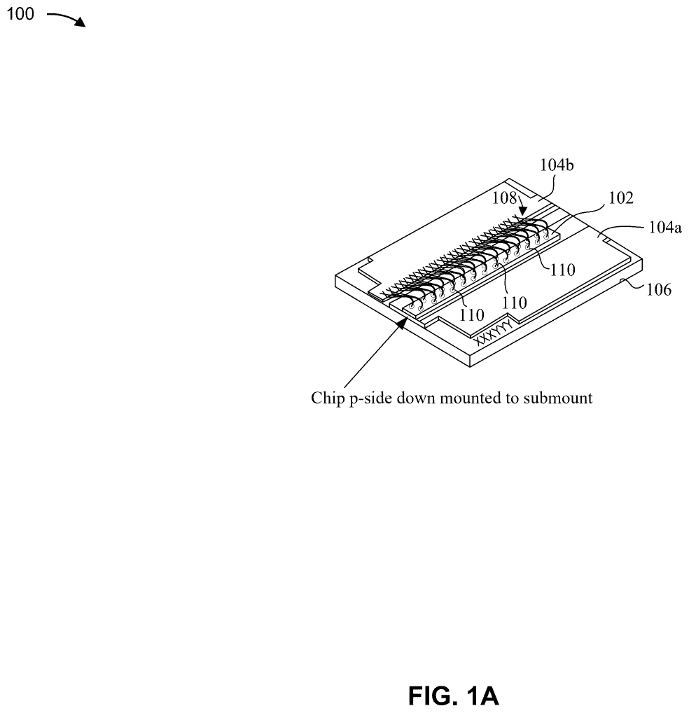

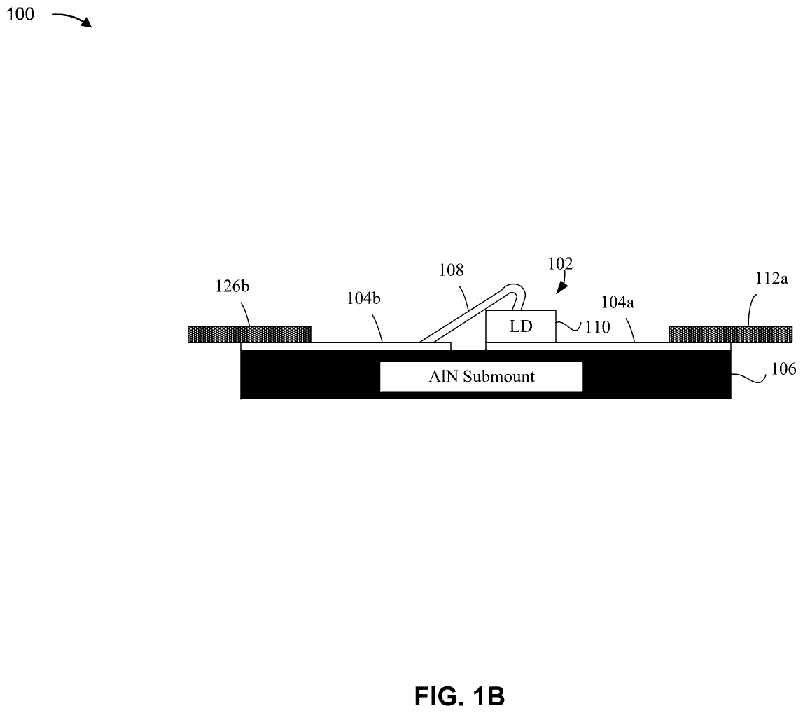

FIGS. 1A and 1B show a CoS module 100 according to one or more implementations. The CoS module 100 may include a laser diode chip 102, a conductive interconnect layer 104 (including an anode portion 104a and a cathode portion 104b), a submount substrate 106, and bond wires 108. The submount substrate 106 may be made of aluminum nitride (AlN), which had a good thermal conductivity for dissipating heat generated by the laser diode chip 102. The laser diode chip 102 may be arranged with its p-side (e.g., anode-side) down to the submount substrate 106. The laser diode chip 102 includes an array of laser diodes 110. The bond wires 108 may provide electrical connections between the cathode portion 104b and cathodes of the array of laser diodes 110. The array of laser diodes 110 may emit light when a current is applied between the anode portion 104a and the cathode portion 104b. In some implementations, bond wires 112a and 112b may be provided to connect one or more CoS modules 100 in series.

As indicated above, FIGS. 1A and 1B are provided as examples. Other examples may differ from what is described with regard to FIGS. 1A and 1B. In practice, the CoS module 100 may include additional components, fewer components, different components, or differently arranged components than those shown in FIGS. 1A and 1B without deviating from the disclosure provided above.

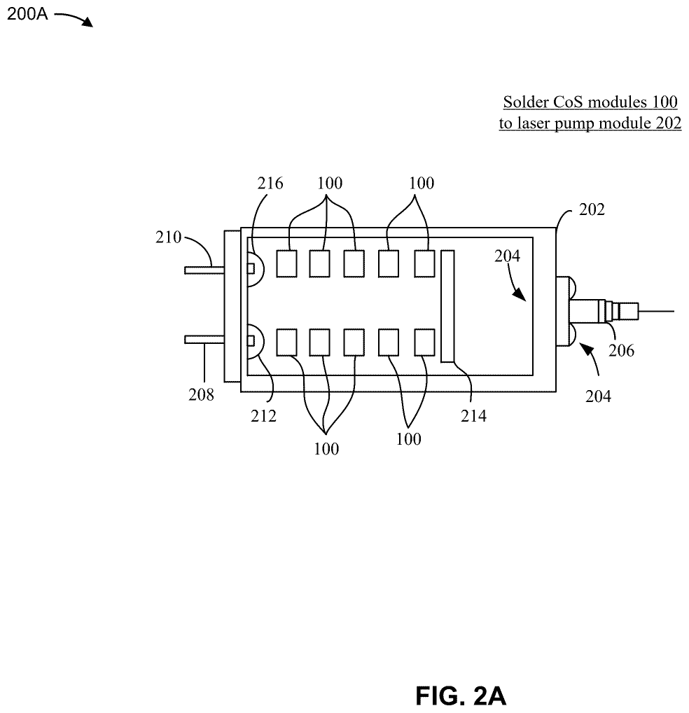

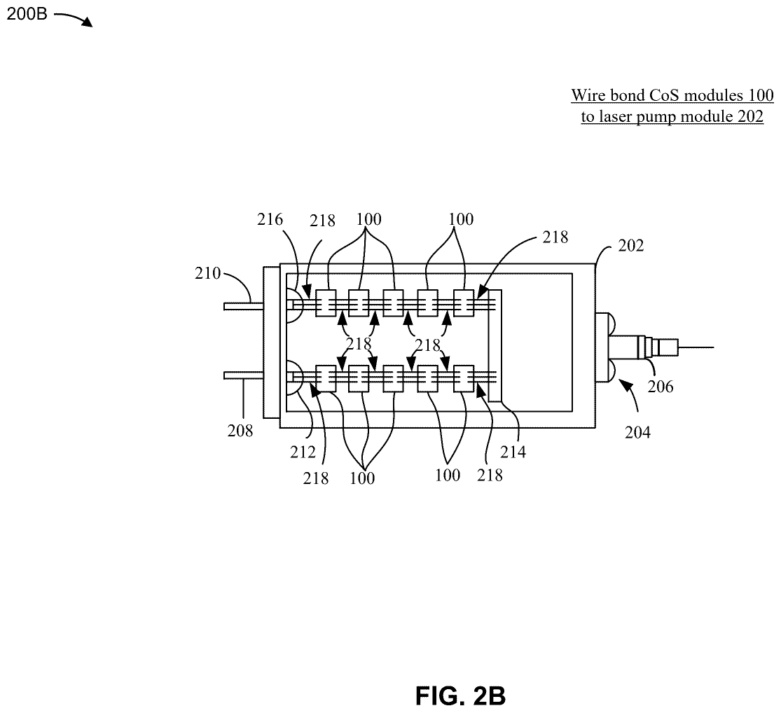

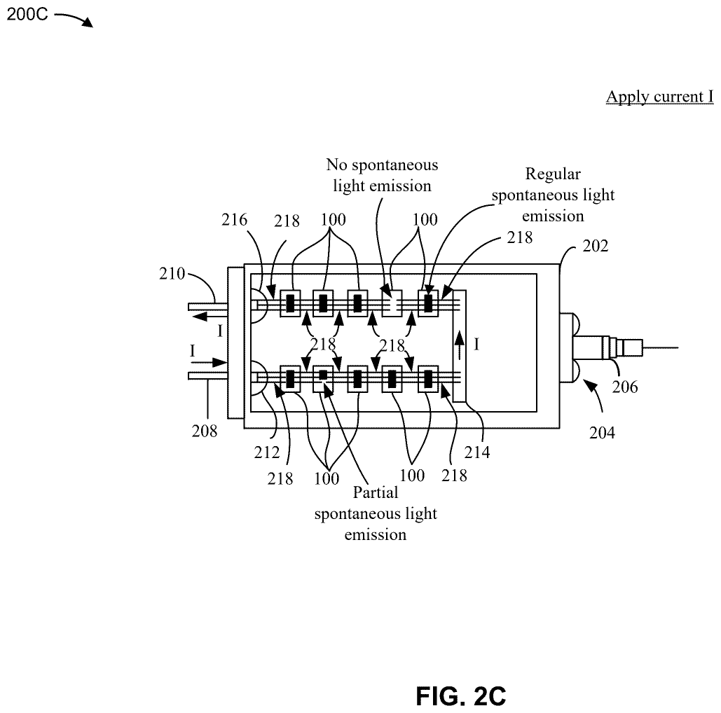

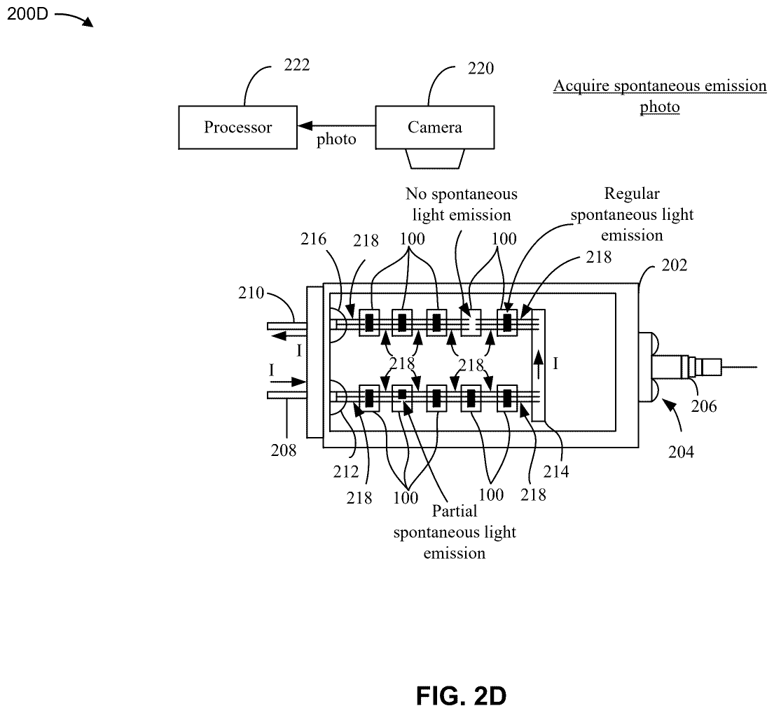

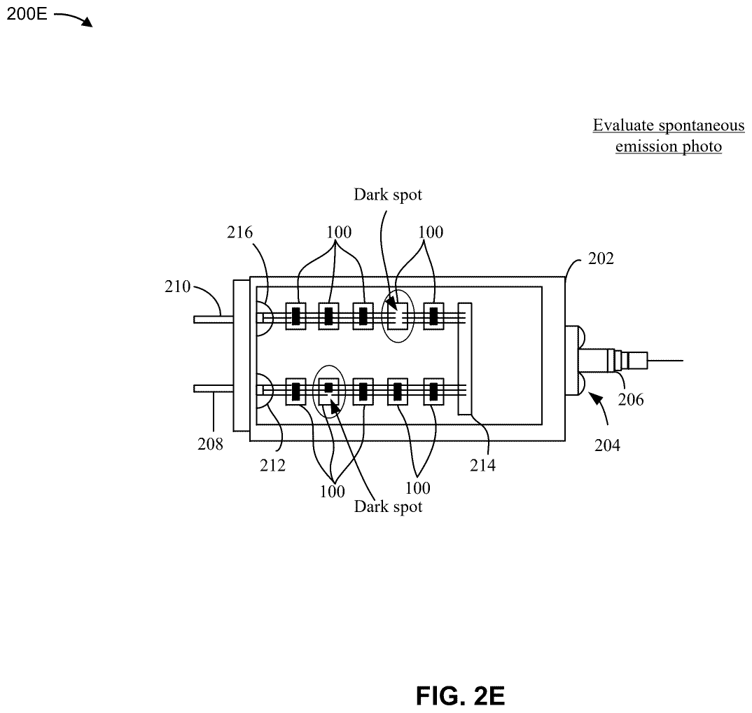

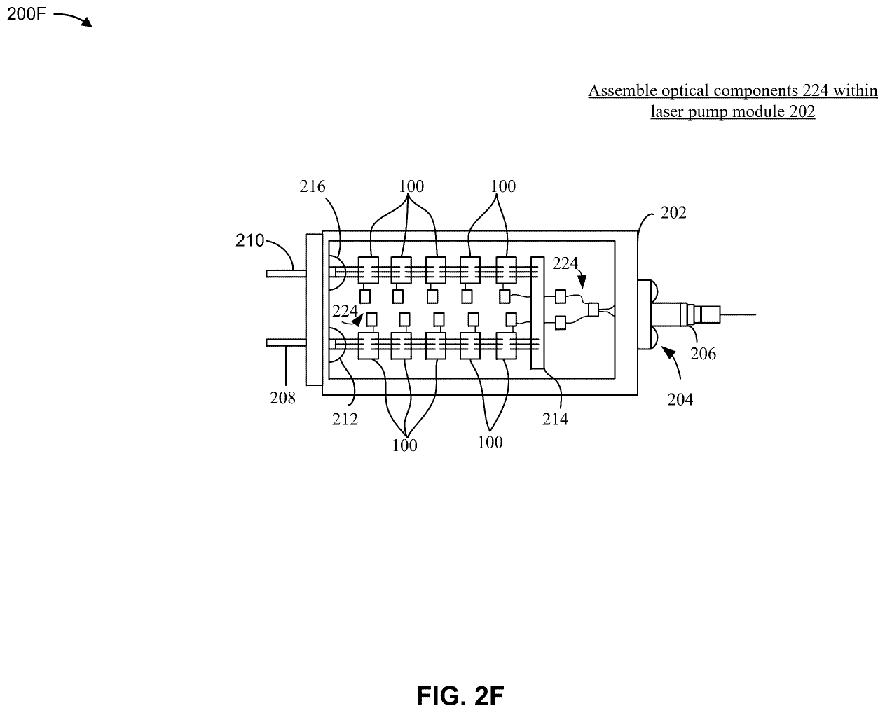

FIGS. 2A-2F show an example process flow, including process stages 200A-200F, for a method of manufacturing a laser pump module 202 according to one or more implementations. A plurality of CoS modules 100 may be assembled for mounting onto the laser pump module 202. Each CoS module 100 may include a respective laser diode chip (e.g., laser diode chip 102) mounted to a respective submount substrate (e.g., submount substrate 106), as described in connection with FIGS. 1A and 1B. Each respective laser diode chip 102 may include a respective array of laser diodes 110.

FIG. 2A shows a first process stage 200A that includes mounting the plurality of CoS modules 100 to the laser pump module 202. The plurality of CoS modules 100 may be soldered to the laser pump module 202.

The laser pump module 202 may include an optical output 204 configured to be coupled to an optical fiber 206, an input conductor 208 configured to receive a current, an output conductor 210 configured to output the current, and one or more electrical conductors 212, 214, and 216 arranged to form a conductive path with the input conductor 208 and the output conductor 210 for conducting the current between the input conductor and the output conductor. The electrical conductor 212 may be part of the input conductor 208 or may be a bond pad coupled to the input conductor 208. The electrical conductor 214 may include a bus bar or other conductive structure. The electrical conductor 216 may be part of the output conductor 210 or may be a bond pad coupled to the output conductor 210.

FIG. 2B shows a second process stage 200B that includes wire bonding each CoS module 100 such that bond wires 218 coupled to the plurality of CoS modules 100 form part of the conductive path. The bond wires 218 may be configured to provide the current to each respective laser diode chip 102 of the plurality of CoS modules 100. The bond wires 218 may be provided such that the plurality of CoS modules 100 are coupled in series along the one or more conductive paths. The bond wires 218 may correspond to the bond wires 112a and 112b described in connection with FIGS. 1A and 1B.

FIG. 2C shows a third process stage 200C that includes applying a current I to the input conductor 208 to generate a spontaneous light emission by each respective laser diode chip 102. The current I is less than a lasing threshold of each respective laser diode chip 102 so as not to produce laser light. When all laser diodes of a respective laser diode chip 102 generate a spontaneous light emission, the respective laser diode chip 102 produces a regular spontaneous light emission and is operating normally. However, when one or more laser diodes of a respective laser diode chip 102 do not generate a spontaneous light emission, the respective laser diode chip 102 may be considered defective. In the example shown in FIG. 2C, two respective laser diode chips 102 (e.g., two CoS modules 100) do not generate a regular spontaneous light emission.

FIG. 2D shows a fourth process stage 200D that includes acquiring, while the current I is applied to the input conductor 208, a spontaneous emission photo of the plurality of CoS modules. A camera 220 may be configured to acquire the spontaneous emission photo and provide the spontaneous emission photo to a processor 222.

FIG. 2E shows a fifth process stage 200E that includes evaluating the spontaneous emission photo for the spontaneous light emission of each respective laser diode chip 102 to obtain an evaluation result. The fifth process stage 200E may further include determining, based on the evaluation result, whether the spontaneous light emission has failed at one or more respective laser diode chips. In some implementations, the evaluating of the spontaneous emission photo for the spontaneous light emission may be performed by human observation. In some implementations, the evaluating of the spontaneous emission photo for the spontaneous light emission may be performed by the processor 222.

For example, evaluating the spontaneous emission photo may include evaluating, in the spontaneous emission photo, for one or more dark laser diodes at each respective laser diode chip 102 (e.g., in each CoS module 100). A dark laser diode is a laser diode that does not emit light. A diode array may be fully dark (e.g., no lasers diodes are functioning) or partially dark, meaning some laser diodes of the diode array emit light, while some other laser diodes of the diode array do not emit light. Evaluating, in the spontaneous emission photo, for one or more dark laser diodes at each respective laser diode chip 102 may include performing, by the processor 222, an image analysis of the spontaneous emission photo, which may include evaluating for one or more dark spots in the spontaneous emission photo at locations corresponding to respective arrays of laser diodes 110 (e.g., at locations corresponding to respective CoS modules 100). The processor 222 may detect each CoS module 100 and may analyze, for each CoS module 100, whether all laser diodes 110 emit light, or whether one or more dark laser diodes are present. Thus, evaluating, in the spontaneous emission photo, for one or more dark laser diodes at each respective laser diode chip 102 may include evaluating, by the processor 222, for one or more dark spots within the spontaneous emission photo at locations corresponding to respective arrays of laser diodes 110.

Determining, based on the evaluation result, whether the spontaneous light emission has failed at one or more respective laser diode chips 102 may include determining, by the processor 222 and based on the processor 222 detecting one or more dark spots in the spontaneous emission photo at a location of a respective laser diode chip 102, that the spontaneous light emission has failed at the respective laser diode chip 102. In addition, determining, based on the evaluation result, whether the spontaneous light emission has failed at one or more respective laser diode chips 102 may include determining, by the processor 222 and based on the processor 222 not detecting one or more dark spots in the spontaneous emission photo at the location of the respective laser diode chip 102, that the spontaneous light emission has succeeded at the respective laser diode chip 102.

Determining, based on the evaluation result, whether the spontaneous light emission has failed at one or more respective laser diode chips 102 may include determining, based on one or more dark laser diodes being detected in the spontaneous emission photo at a respective laser diode chip 102, that the spontaneous light emission has failed at the respective laser diode chip 102, or determining, based on one or more dark laser diodes not being detected in the spontaneous emission photo at the respective laser diode chip 102, that the spontaneous light emission has succeeded at the respective laser diode chip 102.

Evaluating the spontaneous emission photo for the spontaneous light emission of each respective laser diode chip 102 may include evaluating, in the spontaneous emission photo, for one or more dark spots in each respective array of laser diodes 110. Determining, based on the evaluation result, whether the spontaneous light emission has failed at one or more respective laser diode chips 102 may include determining, based on detecting the one or more dark spots, that the spontaneous light emission has failed at one or more respective laser diode chips 102.

The method of manufacturing may further include determining a number of respective laser diode chips 102 at which the spontaneous light emission has failed, and, based on the number of respective laser diode chips 102 satisfying a threshold, halting a production of the laser pump module 202. For example, the processor 222 may be part of or may be representative of a production controller that controls or oversees the manufacturing of the laser pump module. The processor 222 may count the number of respective laser diode chips 102 at which the spontaneous light emission has failed, and halt the production of the laser pump module 202 based on the number of respective laser diode chips 102 satisfying the threshold. In some implementations, the processor 222 may generate an alarm when the number of respective laser diode chips 102 satisfy the threshold. In some implementations, the threshold may be at least two.

In some implementations, the method of manufacturing may further include determining a number of respective laser diode chips 102 at which the spontaneous light emission has failed; and, based on the number of respective laser diode chips 102 satisfying a threshold, halting the production of the laser pump module 202; or, based on the number of respective laser diode chips 102 not satisfying the threshold, assembling optical components within the laser pump module 202. The optical components may be configured to couple optical power from each of the respective laser diode chips 102 (e.g., from each CoS module 100) to the optical output 204. For example, the processor 222 may be part of production controller that controls or oversees the manufacturing of the laser pump module. The processor 222 may count the number of respective laser diode chips 102 at which the spontaneous light emission has failed, and determine whether the production of the laser pump module 202 may proceed further to a next process stage, which may include assembling optical components within the laser pump module 202.

In some implementations, the method of manufacturing may include replacing a CoS module, having a respective laser diode chip 102 at which the spontaneous light emission has failed, with a different CoS module. For example, the processor 222 may modify a production of the laser pump module 202 to replace defective CoS modules with different CoS modules based on the defective CoS modules being detected by the processor 222. In other words, instead of halting the production of the laser pump module 202 (and discarding the laser pump module 202), the method adapts the production of the laser pump module 202 to remove defective CoS modules that have been detected and to solder mount replacement CoS modules into the laser pump module 202. Once the replacement CoS modules have been installed and wire bonded to the laser pump module 202, the processor 222 may cause the current I to be applied to the input conductor 208 to generate a spontaneous light emission by each respective laser diode chip 102, the spontaneous emission photo to be acquired and evaluated to ensure that each respective laser diode chip 102 is functioning normally.

FIG. 2F shows a sixth process stage 200F that includes assembling optical components 224 within the laser pump module 202. The optical components 224 may be configured to couple optical power from each of the respective laser diode chips 102 (e.g., from each CoS module 100) to the optical output 204 for providing laser pump light to the optical fiber 206.

The optical components 224 may include one or more lenses, optical couplers, and/or optical fibers.

As indicated above, FIGS. 2A-2F are provided as examples. Other examples may differ from what is described with regard to FIGS. 2A-2F.

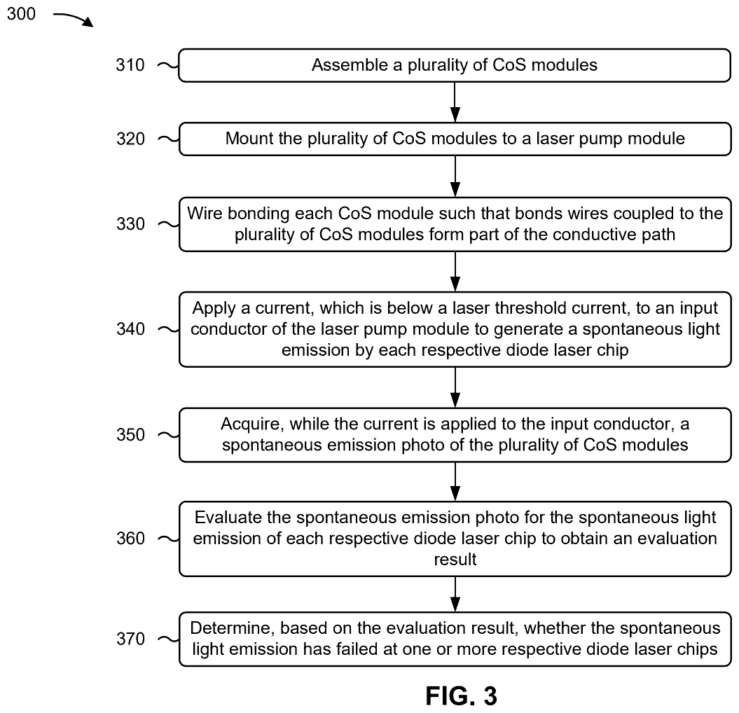

FIG. 3 is a flowchart of an example process 300 associated with early detection of dead laser diodes in a laser pump module. In some implementations, one or more process blocks of FIG. 3 are performed by a manufacturing system.

As shown in FIG. 3, process 300 may include assembling a plurality of CoS modules (block 310). Each CoS module may include a respective laser diode chip mounted to a respective submount substrate. Each respective laser diode chip may include a respective array of laser diodes.

As further shown in FIG. 3, process 300 may include mounting the plurality of CoS modules to the laser pump module (block 320). The laser pump module may include an optical output configured to be coupled to an optical fiber, an input conductor configured to receive a current, an output conductor configured to output the current, and one or more electrical conductors arranged to form a conductive path with the input conductor and the output conductor for conducting the current between the input conductor and the output conductor.

As further shown in FIG. 3, process 300 may include wire bonding each CoS module of the plurality of CoS modules such that bond wires coupled to the plurality of CoS modules form part of the conductive path (block 330). The bond wires may be configured to provide the current to each respective laser diode chip of the plurality of CoS modules.

As further shown in FIG. 3, process 300 may include applying the current to the input conductor to generate a spontaneous light emission by each respective laser diode chip (block 340). The current may be less than a lasing threshold of each respective laser diode chip.

As further shown in FIG. 3, process 300 may include acquiring, while the current is applied to the input conductor, a spontaneous emission photo of the plurality of CoS modules (block 350).

As further shown in FIG. 3, process 300 may include evaluating the spontaneous emission photo for the spontaneous light emission of each respective laser diode chip to obtain an evaluation result (block 360).

As further shown in FIG. 3, process 300 may include determining, based on the evaluation result, whether the spontaneous light emission has failed at one or more respective laser diode chips (block 370).

Process 300 may include additional implementations, such as any single implementation or any combination of implementations described below and/or in connection with one or more other processes described elsewhere herein.

Although FIG. 3 shows example blocks of process 300, in some implementations, process 300 includes additional blocks, fewer blocks, different blocks, or differently arranged blocks than those depicted in FIG. 3. Additionally, or alternatively, two or more of the blocks of process 300 may be performed in parallel.

The following provides an overview of some Aspects of the present disclosure:

Aspect 1: A method of manufacturing a laser pump module, the method comprising: assembling a plurality of chip-on-submount (CoS) modules, wherein each CoS module of the plurality of CoS modules includes a respective laser diode chip mounted to a respective submount substrate, wherein each respective laser diode chip comprises a respective array of laser diodes; mounting the plurality of CoS modules to the laser pump module, wherein the laser pump module includes an optical output configured to be coupled to an optical fiber, an input conductor configured to receive a current, an output conductor configured to output the current, and one or more electrical conductors arranged to form a conductive path with the input conductor and the output conductor for conducting the current between the input conductor and the output conductor; wire bonding each CoS module of the plurality of CoS modules such that bond wires coupled to the plurality of CoS modules form part of the conductive path, wherein the bond wires are configured to provide the current to each respective laser diode chip of the plurality of CoS modules; applying the current to the input conductor to generate a spontaneous light emission by each respective laser diode chip, wherein the current is less than a lasing threshold of each respective laser diode chip; acquiring, while the current is applied to the input conductor, a spontaneous emission photo of the plurality of CoS modules; evaluating the spontaneous emission photo for the spontaneous light emission of each respective laser diode chip to obtain an evaluation result; and determining, based on the evaluation result, whether the spontaneous light emission has failed at one or more respective laser diode chips.

Aspect 2: The method of Aspect 1, wherein evaluating the spontaneous emission photo for the spontaneous light emission of each respective laser diode chip includes: evaluating, in the spontaneous emission photo, for one or more dark laser diodes at each respective laser diode chip.

Aspect 3: The method of Aspect 2, wherein evaluating, in the spontaneous emission photo, for one or more dark laser diodes at each respective laser diode chip includes: performing, by a processor, an image analysis of the spontaneous emission photo, including evaluating for one or more dark spots in the spontaneous emission photo at locations corresponding to respective arrays of laser diodes.

Aspect 4: The method of Aspect 2, wherein evaluating, in the spontaneous emission photo, for one or more dark laser diodes at each respective laser diode chip includes: evaluating, by a processor, for one or more dark spots within the spontaneous emission photo at locations corresponding to respective arrays of laser diodes.

Aspect 5: The method of Aspect 4, wherein determining, based on the evaluation result, whether the spontaneous light emission has failed at one or more respective laser diode chips includes: determining, by the processor and based on the processor detecting one or more dark spots in the spontaneous emission photo at a location of a respective laser diode chip, that the spontaneous light emission has failed at the respective laser diode chip; and determining, by the processor and based on the processor not detecting one or more dark spots in the spontaneous emission photo at the location of the respective laser diode chip, that the spontaneous light emission has succeeded at the respective laser diode chip.

Aspect 6: The method of Aspect 2, wherein determining, based on the evaluation result, whether the spontaneous light emission has failed at one or more respective laser diode chips includes: determining, based on one or more dark laser diodes being detected in the spontaneous emission photo at a respective laser diode chip, that the spontaneous light emission has failed at the respective laser diode chip; or determining, based on one or more dark laser diodes not being detected in the spontaneous emission photo at the respective laser diode chip, that the spontaneous light emission has succeeded at the respective laser diode chip.

Aspect 7: The method of any of Aspects 1-6, wherein evaluating the spontaneous emission photo for the spontaneous light emission of each respective laser diode chip includes: evaluating, in the spontaneous emission photo, for one or more dark spots in each respective array of laser diodes, and wherein determining, based on the evaluation result, whether the spontaneous light emission has failed at one or more respective laser diode chips includes: determining, based on detecting the one or more dark spots, that the spontaneous light emission has failed at one or more respective laser diode chips.

Aspect 8: The method of any of Aspects 1-7, further comprising: determining a number of respective laser diode chips at which the spontaneous light emission has failed; and based on the number of respective laser diode chips satisfying a threshold, halting a production of the laser pump module.

Aspect 9: The method of any of Aspects 1-8, further comprising: determining a number of respective laser diode chips at which the spontaneous light emission has failed; and based on the number of respective laser diode chips satisfying a threshold, halting a production of the laser pump module; or based on the number of respective laser diode chips not satisfying the threshold, assembling optical components within the laser pump module, wherein the optical components are configured to couple optical power from each of the respective laser diode chips to the optical output.

Aspect 10: The method of Aspect 9, wherein the threshold is at least two.

Aspect 11: The method of any of Aspects 1-10, wherein mounting the plurality of CoS modules to the laser pump module includes solder mounting the plurality of CoS modules to the laser pump module.

Aspect 12: The method of any of Aspects 1-11, wherein the spontaneous light emission corresponds to an emission of near-infrared light.

Aspect 13: The method of any of Aspects 1-12, further comprising: replacing a CoS module, having a respective laser diode chip at which the spontaneous light emission has failed, with a different CoS module.

Aspect 14: A method of manufacturing a laser pump module, the method comprising: mounting a plurality of chip-on-submount (CoS) modules to the laser pump module, wherein each CoS module of the plurality of CoS modules includes a respective laser diode chip mounted to a respective submount substrate, wherein each respective laser diode chip comprises a respective array of laser diodes, and wherein the laser pump module includes an optical output configured to be coupled to an optical fiber, and includes one or more electrical conductors; wire bonding the plurality of CoS modules with bond wires, wherein the bond wires are provided such that the plurality of CoS modules form one or more conductive paths with the one or more electrical conductors; applying a current to the one or more conductive paths to cause a spontaneous light emission by each respective laser diode chip, wherein the current is less than a lasing threshold of each respective laser diode chip; acquiring, while the current is applied to the one or more conductive paths, a spontaneous emission photo of the plurality of CoS modules; evaluating the spontaneous emission photo for the spontaneous light emission of each respective laser diode chip to obtain an evaluation result; and determining, based on the evaluation result, whether the spontaneous light emission has failed at one or more respective laser diode chips.

Aspect 15: The method of Aspect 14, wherein the bond wires are provided such that the plurality of CoS modules are coupled in series along the one or more conductive paths.

Aspect 16: The method of any of Aspects 14-15, wherein evaluating the spontaneous emission photo for the spontaneous light emission of each respective laser diode chip includes: evaluating, in the spontaneous emission photo, for one or more dark laser diodes at each respective laser diode chip.

Aspect 17: The method of Aspect 16, wherein evaluating, in the spontaneous emission photo, for one or more dark laser diodes at each respective laser diode chip includes: performing, by a processor, an image analysis of the spontaneous emission photo, including evaluating for one or more dark spots in the spontaneous emission photo at locations corresponding to respective arrays of laser diodes.

Aspect 18: The method of any of Aspects 14-17, wherein evaluating the spontaneous emission photo for the spontaneous light emission of each respective laser diode chip includes: evaluating, by a processor, for one or more dark spots within the spontaneous emission photo at locations corresponding to respective arrays of laser diodes, and wherein determining, based on the evaluation result, whether the spontaneous light emission has failed at one or more respective laser diode chips includes: determining, by the processor and based on the processor detecting one or more dark spots in the spontaneous emission photo at a location of a respective laser diode chip, that the spontaneous light emission has failed at the respective laser diode chip; and determining, by the processor and based on the processor not detecting one or more dark spots in the spontaneous emission photo at the location of the respective laser diode chip, that the spontaneous light emission has succeeded at the respective laser diode chip.

Aspect 19: The method of Aspect 18, further comprising: determining, by the processor, a number of respective laser diode chips at which the spontaneous light emission has failed; and based on the number of respective laser diode chips satisfying a threshold, halting, by a production controller, a production of the laser pump module.

Aspect 20: The method of Aspect 19, further comprising: based on the number of respective laser diode chips not satisfying the threshold, continuing, by the production controller, the production of the laser pump module.

Aspect 21: The method of Aspect 18, further comprising: determining, by the processor, a number of respective laser diode chips at which the spontaneous light emission has failed; and based on the number of respective laser diode chips not satisfying the threshold, assembling optical components within the laser pump module, wherein the optical components are assembled to couple optical power from each of the respective laser diode chips to the optical output.

Aspect 22: The method of any of Aspects 14-21, further comprising: replacing a CoS module, having a respective laser diode chip at which the spontaneous light emission has failed, with a different CoS module.

Aspect 23: A system configured to perform one or more operations recited in one or more of Aspects 1-22.

Aspect 24: An apparatus comprising means for performing one or more operations recited in one or more of Aspects 1-22.

Aspect 25: A non-transitory computer-readable medium storing a set of instructions, the set of instructions comprising one or more instructions that, when executed by a device, cause the device to perform one or more operations recited in one or more of Aspects 1-22.

Aspect 26: A computer program product comprising instructions or code for executing one or more operations recited in one or more of Aspects 1-22.

The foregoing disclosure provides illustration and description, but is not intended to be exhaustive or to limit the implementations to the precise forms disclosed. Modifications and variations may be made in light of the above disclosure or may be acquired from practice of the implementations. Furthermore, any of the implementations described herein may be combined unless the foregoing disclosure expressly provides a reason that one or more implementations may not be combined.

As used herein, the term “component” is intended to be broadly construed as hardware, firmware, and/or a combination of hardware and software. It will be apparent that systems and/or methods described herein may be implemented in different forms of hardware, firmware, or a combination of hardware and software. The actual specialized control hardware or software code used to implement these systems and/or methods is not limiting of the implementations.

Thus, the operation and behavior of the systems and/or methods are described herein without reference to specific software code—it being understood that software and hardware can be designed to implement the systems and/or methods based on the description herein.

As used herein, satisfying a threshold may, depending on the context, refer to a value being greater than the threshold, greater than or equal to the threshold, less than the threshold, less than or equal to the threshold, equal to the threshold, not equal to the threshold, or the like.

Even though particular combinations of features are recited in the claims and/or disclosed in the specification, these combinations are not intended to limit the disclosure of various implementations. In fact, many of these features may be combined in ways not specifically recited in the claims and/or disclosed in the specification. Although each dependent claim listed below may directly depend on only one claim, the disclosure of various implementations includes each dependent claim in combination with every other claim in the claim set. As used herein, a phrase referring to “at least one of” a list of items refers to any combination of those items, including single members. As an example, “at least one of: a, b, or c” is intended to cover a, b, c, a-b, a-c, b-c, and a-b-c, as well as any combination with multiple of the same item.

When a component or one or more components (e.g., a laser emitter or one or more laser emitters) is described or claimed (within a single claim or across multiple claims) as performing multiple operations or being configured to perform multiple operations, this language is intended to broadly cover a variety of architectures and environments. For example, unless explicitly claimed otherwise (e.g., via the use of “first component” and “second component” or other language that differentiates components in the claims), this language is intended to cover a single component performing or being configured to perform all of the operations, a group of components collectively performing or being configured to perform all of the operations, a first component performing or being configured to perform a first operation and a second component performing or being configured to perform a second operation, or any combination of components performing or being configured to perform the operations. For example, when a claim has the form “one or more components configured to: perform X; perform Y; and perform Z,” that claim should be interpreted to mean “one or more components configured to perform X; one or more (possibly different) components configured to perform Y; and one or more (also possibly different) components configured to perform Z.”

No element, act, or instruction used herein should be construed as critical or essential unless explicitly described as such. Also, as used herein, the articles “a” and “an” are intended to include one or more items, and may be used interchangeably with “one or more. ” Further, as used herein, the article “the” is intended to include one or more items referenced in connection with the article “the” and may be used interchangeably with “the one or more. ” Furthermore, as used herein, the term “set” is intended to include one or more items (e.g., related items, unrelated items, or a combination of related and unrelated items), and may be used interchangeably with “one or more. ” Where only one item is intended, the phrase “only one” or similar language is used. Also, as used herein, the terms “has,” “have,” “having,” or the like are intended to be open-ended terms. Further, the phrase “based on” is intended to mean “based, at least in part, on” unless explicitly stated otherwise. Also, as used herein, the term “or” is intended to be inclusive when used in a series and may be used interchangeably with “and/or,” unless explicitly stated otherwise (e.g., if used in combination with “either” or “only one of”).

What is claimed is:

1. A method of manufacturing a laser pump module, the method comprising:
assembling a plurality of chip-on-submount (CoS) modules, wherein each CoS module of the plurality of CoS modules includes a respective laser diode chip mounted to a respective submount substrate, wherein each respective laser diode chip comprises a respective array of laser diodes;
mounting the plurality of CoS modules to the laser pump module, wherein the laser pump module includes an optical output configured to be coupled to an optical fiber, an input conductor configured to receive a current, an output conductor configured to output the current, and one or more electrical conductors arranged to form a conductive path with the input conductor and the output conductor for conducting the current between the input conductor and the output conductor;
wire bonding each CoS module of the plurality of CoS modules such that bond wires coupled to the plurality of CoS modules form part of the conductive path, wherein the bond wires are configured to provide the current to each respective laser diode chip of the plurality of CoS modules;
applying the current to the input conductor to generate a spontaneous light emission by each respective laser diode chip, wherein the current is less than a lasing threshold of each respective laser diode chip;
acquiring, while the current is applied to the input conductor, a spontaneous emission photo of the plurality of CoS modules;
evaluating the spontaneous emission photo for the spontaneous light emission of each respective laser diode chip to obtain an evaluation result; and
determining, based on the evaluation result, whether the spontaneous light emission has failed at one or more respective laser diode chips.

2. The method of claim 1, wherein evaluating the spontaneous emission photo for the spontaneous light emission of each respective laser diode chip includes:
evaluating, in the spontaneous emission photo, for one or more dark laser diodes at each respective laser diode chip.

3. The method of claim 2, wherein evaluating, in the spontaneous emission photo, for one or more dark laser diodes at each respective laser diode chip includes:
performing, by a processor, an image analysis of the spontaneous emission photo, including evaluating for one or more dark spots in the spontaneous emission photo at locations corresponding to respective arrays of laser diodes.

4. The method of claim 2, wherein evaluating, in the spontaneous emission photo, for one or more dark laser diodes at each respective laser diode chip includes:
evaluating, by a processor, for one or more dark spots within the spontaneous emission photo at locations corresponding to respective arrays of laser diodes.

5. The method of claim 4, wherein determining, based on the evaluation result, whether the spontaneous light emission has failed at one or more respective laser diode chips includes:
determining, by the processor and based on the processor detecting one or more dark spots in the spontaneous emission photo at a location of a respective laser diode chip, that the spontaneous light emission has failed at the respective laser diode chip; and
determining, by the processor and based on the processor not detecting one or more dark spots in the spontaneous emission photo at the location of the respective laser diode chip, that the spontaneous light emission has succeeded at the respective laser diode chip.

6. The method of claim 2, wherein determining, based on the evaluation result, whether the spontaneous light emission has failed at one or more respective laser diode chips includes:
determining, based on one or more dark laser diodes being detected in the spontaneous emission photo at a respective laser diode chip, that the spontaneous light emission has failed at the respective laser diode chip; or
determining, based on one or more dark laser diodes not being detected in the spontaneous emission photo at the respective laser diode chip, that the spontaneous light emission has succeeded at the respective laser diode chip.

7. The method of claim 1, wherein evaluating the spontaneous emission photo for the spontaneous light emission of each respective laser diode chip includes:
evaluating, in the spontaneous emission photo, for one or more dark spots in each respective array of laser diodes, and
wherein determining, based on the evaluation result, whether the spontaneous light emission has failed at one or more respective laser diode chips includes:
determining, based on detecting the one or more dark spots, that the spontaneous light emission has failed at one or more respective laser diode chips.

8. The method of claim 1, further comprising:
determining a number of respective laser diode chips at which the spontaneous light emission has failed; and
based on the number of respective laser diode chips satisfying a threshold, halting a production of the laser pump module.

9. The method of claim 1, further comprising:
determining a number of respective laser diode chips at which the spontaneous light emission has failed; and
based on the number of respective laser diode chips satisfying a threshold, halting a production of the laser pump module; or
based on the number of respective laser diode chips not satisfying the threshold, assembling optical components within the laser pump module, wherein the optical components are configured to couple optical power from each of the respective laser diode chips to the optical output.

10. The method of claim 9, wherein the threshold is at least two.

11. The method of claim 1, wherein mounting the plurality of CoS modules to the laser pump module includes solder mounting the plurality of CoS modules to the laser pump module.

12. The method of claim 1, wherein the spontaneous light emission corresponds to an emission of near-infrared light.

13. The method of claim 1, further comprising:
replacing a CoS module, having a respective laser diode chip at which the spontaneous light emission has failed, with a different CoS module.

14. A method of manufacturing a laser pump module, the method comprising:
mounting a plurality of chip-on-submount (CoS) modules to the laser pump module,
wherein each CoS module of the plurality of CoS modules includes a respective laser diode chip mounted to a respective submount substrate, wherein each respective laser diode chip comprises a respective array of laser diodes, and
wherein the laser pump module includes an optical output configured to be coupled to an optical fiber, and includes one or more electrical conductors;
wire bonding the plurality of CoS modules with bond wires, wherein the bond wires are provided such that the plurality of CoS modules form one or more conductive paths with the one or more electrical conductors;
applying a current to the one or more conductive paths to cause a spontaneous light emission by each respective laser diode chip, wherein the current is less than a lasing threshold of each respective laser diode chip;
acquiring, while the current is applied to the one or more conductive paths, a spontaneous emission photo of the plurality of CoS modules;
evaluating the spontaneous emission photo for the spontaneous light emission of each respective laser diode chip to obtain an evaluation result; and
determining, based on the evaluation result, whether the spontaneous light emission has failed at one or more respective laser diode chips.

15. The method of claim 14, wherein the bond wires are provided such that the plurality of CoS modules are coupled in series along the one or more conductive paths.

16. The method of claim 14, wherein evaluating the spontaneous emission photo for the spontaneous light emission of each respective laser diode chip includes:
evaluating, in the spontaneous emission photo, for one or more dark laser diodes at each respective laser diode chip.

17. The method of claim 16, wherein evaluating, in the spontaneous emission photo, for one or more dark laser diodes at each respective laser diode chip includes:
performing, by a processor, an image analysis of the spontaneous emission photo, including evaluating for one or more dark spots in the spontaneous emission photo at locations corresponding to respective arrays of laser diodes.

18. The method of claim 14, wherein evaluating the spontaneous emission photo for the spontaneous light emission of each respective laser diode chip includes:
evaluating, by a processor, for one or more dark spots within the spontaneous emission photo at locations corresponding to respective arrays of laser diodes, and
wherein determining, based on the evaluation result, whether the spontaneous light emission has failed at one or more respective laser diode chips includes:
determining, by the processor and based on the processor detecting one or more dark spots in the spontaneous emission photo at a location of a respective laser diode chip, that the spontaneous light emission has failed at the respective laser diode chip; and
determining, by the processor and based on the processor not detecting one or more dark spots in the spontaneous emission photo at the location of the respective laser diode chip, that the spontaneous light emission has succeeded at the respective laser diode chip.

19. The method of claim 18, further comprising:
determining, by the processor, a number of respective laser diode chips at which the spontaneous light emission has failed; and
based on the number of respective laser diode chips satisfying a threshold, halting, by a production controller, a production of the laser pump module.

20. The method of claim 19, further comprising:
based on the number of respective laser diode chips not satisfying the threshold, continuing, by the production controller, the production of the laser pump module.

21. The method of claim 18, further comprising:
determining, by the processor, a number of respective laser diode chips at which the spontaneous light emission has failed; and
based on the number of respective laser diode chips not satisfying a threshold, assembling optical components within the laser pump module, wherein the optical components are assembled to couple optical power from each of the respective laser diode chips to the optical output.

22. The method of claim 14, further comprising:
replacing a CoS module, having a respective laser diode chip at which the spontaneous light emission has failed, with a different CoS module.
